(19) United States
(12) Patent Application Publication
(10) Pub. No.: US 2025/0374515 A1
(43) Pub. Date: Dec. 4, 2025

(54) THREE-DIMENSIONAL STACKED DRAM DEVICE WITH SUB 4F2 STRUCTURE CELLS

(71) Applicant: TAESUNG ENVIRONMENTAL RESEARCH INSTITUTE CO., LTD., Ulsan (KR)

(72) Inventors: Gi Yeol Yun, Ulsan (KR); Seok Man Kim, Ulsan (KR); Chai Rok Lim, Ulsan (KR); Hyeok-Je Jeong, Gimhae-si (KR); Myung-Kon Jo, Ulsan (KR)

(73) Assignee: TAESUNG ENVIRONMENTAL RESEARCH INSTITUTE CO., LTD., Ulsan (KR)

(21) Appl. No.: 18/678,698

(22) Filed: May 30, 2024

(30) Foreign Application Priority Data
May 30, 2024 (KR) 10-2024-0071062

(51) Int. Cl. H10B 12/00

(52) U.S. Cl. CPC H10B 12/30

(57) ABSTRACT

A DRAM device including a substrate; a plurality of first conductive lines; a plurality of second conductive lines located on the first conductive line a plurality of channel patterns arranged in a honeycomb structure on the first conductive line; and a gate insulating pattern located between the plurality of channel patterns and the plurality of second conductive lines; wherein the plurality of second conductive lines comprise a first subline and a second subline which are at different distances from the first conductive line, and the first subline and the second subline are provided alternating with each other in the first direction, and the plurality of channel patterns located on the single first conductive line are arranged in zigzag along both edges of the single first conductive line, and the plurality of channel patterns contacting the single second conductive line are arranged in a straight line.

### TECHNICAL FIELD

The present invention relates to a DRAM device. More specifically, the present invention relates to a three-dimensional stacked DRAM device with sub 4F2 structure cells.

### BACKGROUND ART

As the density of semiconductor memory devices increases, the cell structure is changing from 8F2 and 6F2 to 4F2 in order to reduce the area occupied by each unit cell in a planar plane. As such, various methods have been suggested to form components such as transistors, bit lines, word lines, capacitors, etc. in response to the decrease in the area of the unit cell. In particular, in order to implement a 4F2 cell structure, a DRAM device comprising a vertical channel transistor that induces a vertical channel by disposing a source and a drain vertically has been suggested (non-patent reference 1).

However, in the DRAM device of non-patent reference 1, the vertical pillar is in direct contact with the cell capacitor, causing leakage current to flow during data storage. Accordingly, the DRAM device has a short retention time, requiring frequent refresh operations and high power consumption.

Meanwhile, in the field of semiconductors, there has been a continuous progress in the direction of reducing the minimum feature size F and pursuing smaller cell layouts in order to increase the capacity per unit area. Recently, however, the increase in capacity per unit area by reducing the minimum feature size F has reached a physical limitation, and accordingly, it is no longer possible to expect an increase in capacity per unit area by the DRAM device of non-patent reference 1.

In addition, since the conventional two-dimensional or planar DRAM device is mainly determined by the area of the unit memory cell as described above, in order to increase the density of the DRAM device, a DRAM device with a three-dimensional structure which has memory cells arranged in three dimensions has been suggested in order to overcome the limitations of the two-dimensional structure, which has reached a physical limitation.

### PRIOR ART REFERENCE

### Non-Patent Reference

(Non-patent reference 1) Chung et al., “Novel 4F2 DRAM Cell with Vertical Pillar Transistor (VPT)” 2011 Proceedings of the European Solid-State Device Research Conference (ESSDERC), 2011

### SUMMARY OF INVENTION

### Technical Task

One of the many objects of the present invention is to provide a vertical channel transistor capable of extending retention time and a DRAM device comprising the same.

In addition, another object of the many objects of the present invention is to provide a vertical channel transistor capable of increasing the capacity per unit area and a three-dimensional stacked DRAM device applying the same.

### Means for Solving Technical Task

According to an aspect, a DRAM device, comprising: a substrate; a plurality of first conductive lines oriented in a first direction perpendicular to an upper surface of the substrate, and disposed parallel to each other at predetermined intervals; a plurality of second conductive lines located on the first conductive line, and disposed parallel to each other in a second direction perpendicular to the first conductive line at predetermined intervals; a plurality of channel patterns arranged in a honeycomb structure on the first conductive line, the plurality of channel patterns each extending in a third direction perpendicular to both the first direction and the second direction; and a gate insulating pattern located between the plurality of channel patterns and the plurality of second conductive lines, wherein the plurality of second conductive lines comprise a first subline and a second subline which are at different distances from the first conductive line, and the first subline and the second subline are provided alternating with each other in the first direction, and the plurality of channel patterns located on the single first conductive line are arranged in zigzag along both edges of the single first conductive line, and the plurality of channel patterns contacting the single second conductive line are arranged in a straight line, is provided.

In an embodiment, the DRAM device may further comprise a gate electrode arranged between the second conductive line and the gate insulating pattern.

According to another aspect, a DRAM device, comprising: a substrate; a plurality of first conductive lines oriented in a first direction perpendicular to an upper surface of the substrate, and disposed parallel to each other at predetermined intervals; a plurality of second conductive lines located on the first conductive line, and disposed parallel to each other in a second direction perpendicular to the first conductive line at predetermined intervals; a plurality of third conductive lines located on the first conductive line, contacting the first conductive line on an opposite side of the second conductive line, and disposed parallel to each other in a second direction perpendicular to the first conductive line at predetermined intervals; a plurality of channel patterns arranged in a honeycomb structure on the first conductive line, the plurality of channel patterns each extending in a third direction perpendicular to both the first direction and the second direction; and a gate insulating pattern located between the plurality of channel patterns and the plurality of second conductive lines or the plurality of third conductive lines, wherein the plurality of second conductive lines comprise a first subline and a second subline which are at different distances from the first conductive line, and the first subline and the second subline are provided alternating with each other in the second direction, the plurality of third conductive lines comprise a third subline and a fourth subline which are at different distances from the first conductive line, and the third subline and the fourth subline are provided alternating with each other in the second direction, and the plurality of channel patterns located on the single first conductive line are arranged in zigzag along both edges of the single first conductive line, and the plurality of channel patterns contacting the single second conductive line or the third conductive line are arranged in a straight line, is provided.

In an embodiment, the DRAM device may further comprise a gate electrode arranged between the second conductive line or the third conductive line and the gate insulating pattern.

### Effect of invention

The DRAM device according to an aspect of the present invention suppresses leakage current generation and extends retention time

In addition, the DRAM device according to an aspect of the present invention has excellent data retention characteristics and low power consumption.

Furthermore, the DRAM device according to an aspect of the present invention facilitates the increase in the capacity per unit area, and has excellent density due to its three-dimensional arrangement.

The effects of an aspect of the present specification are not limited to the above-mentioned effects, and it should be understood that the effects of the present specification include all effects that could be inferred from the configuration described in the detailed description of the specification or the appended claims.

### BRIEF DESCRIPTION OF DRAWINGS

FIG. 1 is a perspective view of a vertical channel transistor according to an embodiment of the present invention;

FIG. 2 is a cross-sectional view taken along A-A′ of FIG. 1;

FIG. 3 is a cross-sectional view taken along B-B′ of FIG. 1;

FIG. 4 is a plan view of the xz-plane of the vertical channel transistor of FIG. 1;

FIG. 5 is a perspective view of a DRAM device comprising the vertical channel transistor of FIG. 1;

FIG. 6 is a view of a vertical channel transistor according to a first modification example;

(a) of FIG. 7 is a plan view of a DRAM device comprising a vertical channel transistor with conventional 4F2 structure; and

(b) of FIG. 7 is a plan view of a DRAM device comprising a vertical channel transistor wherein (3) the intervals between adjacent word lines are reduced to one-half (½) compared to (1) the width of the word line, (2) the width of the bit line, and (4) the intervals between adjacent bit lines.

### BEST MODE FOR CARRYING OUT THE INVENTION

Hereinafter, an aspect of the present invention will be explained with reference to the accompanying drawings. However, the present invention may be implemented in various different forms, and is not intended to be limited to the embodiments set forth herein.

Throughout the specification, it will be understood that when a portion is referred to as being “connected” to another portion, it can be “directly connected to” the other portion, or “indirectly connected to” the other portion having intervening portions present. In addition, when a member is referred to as being located “on,” “on an upper part of,” “on an upper end of,” “under,” “on a lower part of,” “on a lower end of” another member, this includes not only when a member is adjacent to another member, but also when there is another member between the two members.

Throughout this specification, when a component “includes” an element, unless there is another opposite description thereto, it should be understood that the component does not exclude another element but may further include another element.

The embodiments described herein will be described with reference to the cross-sectional views and/or schematic drawings, which are idealized illustrations of the present invention. In addition, throughout the specification, like reference numerals refer to like components. Detailed descriptions of known features and configurations which may obscure the gist of the present invention are hereby omitted, and each component in each of the drawings illustrating the present invention may be somewhat enlarged or reduced in size for ease of description.

Further, embodiments of the present invention are not limited to specific shapes illustrated, but also include variations in shape produced by the manufacturing process.

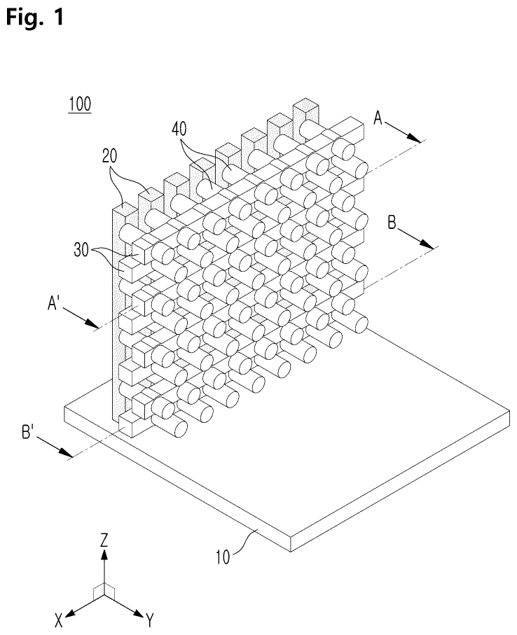

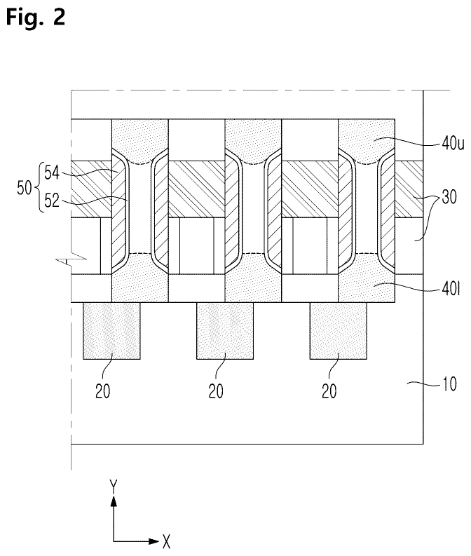

FIG. 1 is a schematic perspective view of a vertical channel transistor according to an embodiment of the present invention.

Referring to FIG. 1, a vertical channel transistor 100 according to an embodiment of the present invention comprises: a substrate 10; a plurality of first conductive lines 20 oriented in a first direction (e.g., a Z-axis direction) perpendicular to an upper surface of the substrate 10, and disposed parallel to each other at predetermined intervals; a plurality of second conductive lines 30 located on the first conductive line 20, and disposed parallel to each other in a second direction (e.g., an X-axis direction) perpendicular to the first conductive line 20 at predetermined intervals; a plurality of channel patterns arranged in a honeycomb structure on the first conductive line, the plurality of channel patterns each extending in a third direction perpendicular to both the first direction (e.g., a Z-axis direction) and the second direction (e.g., an X-axis direction); and a gate insulating pattern (not shown) located between the plurality of channel patterns 40 and the plurality of second conductive lines 30.

The plurality of second conductive lines 30 comprise a first subline 30u and a second subline 30l which are at different distances from the first conductive line 20, and the first subline and the second subline are provided alternating with each other in the second direction (e.g., an X-axis direction), and the plurality of channel patterns 40 located on the single first conductive line 20 are arranged in zigzag along both edges of the single first conductive line 20, and the plurality of channel patterns 40 contacting the single second conductive line 30 are arranged in a straight line.

The vertical channel transistor 100 according to an embodiment of the present invention has a plurality of first conductive lines 20 and a plurality of second conductive lines 30u and 30l intersecting each other. Each first conductive line 20 may extend in a first direction (e.g., a Z-axis direction) perpendicular to the substrate 10, and each second conductive line 30u and 30l may extend in a second direction (e.g., an X-axis direction) intersecting the first direction.

A plurality of channel patterns 40 are disposed at the points where the plurality of first conductive lines 20 and the plurality of second conductive lines 30u and 30l intersect.

Electrodes (not shown) are formed, respectively, at an upper part and a lower part of the plurality of channel patterns 40. A gate (not shown) is formed to enclose a side surface between the upper electrode and the lower electrode, and the gate may comprise a gate insulating pattern and a gate conducting pattern.

The plurality of second conductive lines 30u and 30l comprise a first subline 30u and a second subline 30l which are at different distances from the first conductive line 20, and the first subline and the second subline are provided alternating with each other in the second direction (e.g., an X-axis direction).

Preferably, the first conductive line 20 may be a bit line, and the second conductive line 30 may be a word line, but is not limited thereto.

In the conventional vertical channel transistor, the plurality of word lines are disposed side by side at substantially the same height, and thus there are physical limitations to increasing the capacity per unit area.

However, in the present invention, since adjacent word lines are disposed at different distances from the bit lines, the minimum feature size F may be easily reduced, thereby increasing the capacity per unit area and improving the density.

In addition, the present inventors realized that a three-dimensional stacking structure in which the conventional bit lines are oriented perpendicular to the substrate and the word lines are placed thereon at different distances from the substrate can be applied to improve the density more effectively, and completed the present invention.

The first and second sublines 30u and 30l may be formed independently of each other of at least one material among metal, semiconductor and alloy, and may be formed of the same material or may be formed of different materials.

A spacer (not shown) may be provided at a side wall of the first and second sublines 30u and 30l. The spacer may prevent contact with other channel patterns 40 which are not interconnected by the first and second word lines 30u and 30l.

FIG. 2 is a cross-sectional view taken along A-A′ of FIG. 1.

The substrate 10 may include, for example, a group IV semiconductor material such as silicon (Si), germanium (Ge), silicon germanium (SiGe), silicon carbide (SiC), a group III-V semiconductor material such as gallium arsenide (GaAs), indium arsenide (InAs), indium phosphide (InP), an oxide semiconductor, a nitride semiconductor, a nitrogen oxide semiconductor, etc. Specifically, the substrate may be a silicon substrate doped with n-type impurities, but is not limited thereto.

Each of the plurality of channel patterns 40 may extend in a direction parallel to the substrate 10. Here, each channel pattern 40 may be provided in a third direction (e.g., a Y-axis direction) that is parallel to an upper surface to the substrate 10 in contact with the first conductive line 20, and perpendicular to both the first direction and the second direction. Each channel pattern 40 may comprise the same semiconductor material as the substrate 10.

Each of the plurality of channel patterns 40 may comprise a source region as an upper electrode 40u and a drain region as a lower electrode 40l. The lower electrode 40l may be electrically connected to the bit line 20, and the upper electrode 40u may be electrically connected to a capacitor (not shown) which will be described later. The positions of the source region and the drain region may vary as needed, and the upper electrode 40u may function as a drain region and the lower electrode 40l may function as a source region.

In the channel pattern 40, the region between the upper electrode 40u and the lower electrode 40l, which is the body region (not shown), has the same polarity as the substrate 10, and the upper electrode 40u and the lower electrode 40l have a different polarity from the substrate 10. For example, when the substrate 10 is a p-type semiconductor substrate, the body region has a p-type polarity, and the upper electrode 40u and the lower electrode 40l have an n-type polarity. In this case, the upper electrode 40u and the lower electrode 40l may be formed by implanting n-type impurity ions into each of the upper end and the lower end of the channel pattern 40 and performing drive-in diffusion.

A gate 50 is formed between the upper electrode and the lower electrode to enclose a side surface of the channel pattern 40, and the gate 50 may comprise a gate insulating pattern 52 and a gate conducting pattern 54.

The first conductive line 20 is arranged to extend along a first direction (e.g., a Z-axis direction) on a lower part of the lower electrode 40l, and each first conductive line 20 may electrically connect the lower electrode 40l arranged along the first direction. The first conductive line 20 is formed in the interior of the substrate 10, and thus may comprise the same semiconductor material as the substrate 10.

Each of the plurality of the first sublines 30u is provided at a height corresponding to an upper part of a gate 50 formed on a side surface of the channel pattern 40. Additionally, each first subline 30u may be provided to enclose at least a portion of the upper part of the gate 50.

The first subline 30u may comprise a conductive material. For example, the first subline 30u may comprise at least one of metal, semiconductor and alloy. Specifically, the first subline 30u may comprise one or more metals selected from the group consisting of aluminum, tungsten, molybdenum, titanium, and tantalum, and one or more semiconductors selected from the group consisting of group IV semiconductors, group III-V semiconductors, oxide semiconductors, nitride semiconductors, and nitrogen oxide semiconductors, but is not limited thereto.

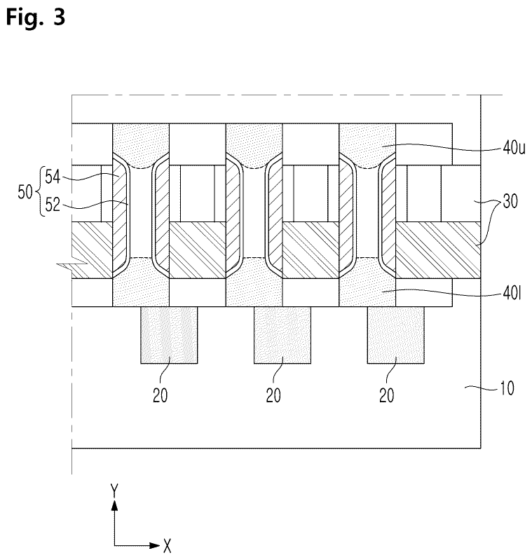

FIG. 3 is a cross-sectional view taken along B-B′ of FIG. 1.

Referring to FIG. 3, the plurality of channel patterns 40 are in common contact with the second subline 30l, and specifically, each second subline 30l is provided at a height corresponding to the lower part of the gate 50 formed on a side surface of the channel pattern 40. Additionally, each first subline 30u is provided to enclose at least a portion of the lower part of the gate 50.

The second subline 30l is disposed at a height different from the first subline 30u when viewed in a cross-section cut in the xy plane, and specifically, the second subline 30l is disposed at a lower position than the first subline 30u. As such, since adjacent first and second sublines 30u and 30l are disposed at different heights, the minimum feature size F may be easily reduced, thereby increasing the capacity per unit area and improving the density.

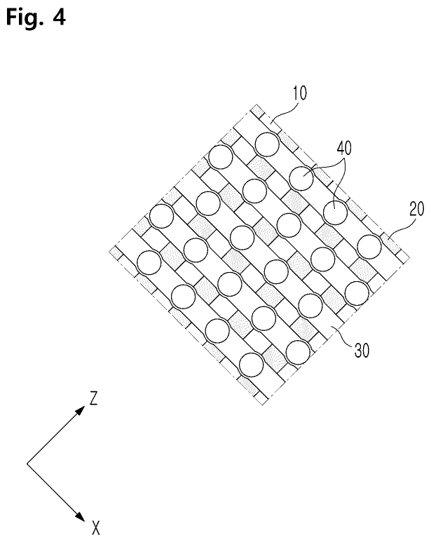

FIG. 4 is a plan view of the xz-plane of the vertical channel transistor of FIG. 1;

Referring to FIG. 4, the plurality of channel patterns 40 are disposed in a honeycomb structure on the first conductive line 20.

Here, a honeycomb structure is a structure in which channel patterns are disposed in the center point and each of the six vertices of a hexagon. Each of the channel patterns located at the six vertices becomes the center point of each of the six neighboring hexagons.

In a honeycomb structure, the hexagon may be an equilateral hexagon, and all six triangles sharing the center point may be equilateral triangles.

As such, as the plurality of channel patterns 40 are disposed in a honeycomb structure, the sub 4F2 structure may be achieved without adjusting the width of the first conductive line 20, the width of the second conductive lines 30l and 30u, and the intervals between adjacent first conductive lines 20. For example, assuming that the diameter of each channel pattern 40, the width of the first conductive line 20, the width of the second conductive lines 30l and 30u, and the intervals between adjacent first conductive lines 20 are all the same as F, the area of a parallelogram, which is a rectangle connecting the four channel patterns, becomes about 3.464F2(=2F×2F sin 60°). As a result, the sub 4F2 structure may be easily achieved without increasing the bit line-to-bit line capacitance, the bit line-to-word line capacitance, and the bit line-to-substrate capacitance, while maintaining the ratio Cb/Cs of bit line capacitance Cb to cell capacitance Cs at the same level as conventionally.

As the plurality of channel patterns 40 have a honeycomb structure, the plurality of channel patterns 40 located on the single bit line are arranged in zigzag along both edges of the single bit line, and the plurality of channel patterns 40 contacting the single word line are arranged in a straight line.

Assuming that the diameter of each channel pattern 40, the width of the first conductive line 20, and the intervals between adjacent first conductive lines 20 are all the same as F, the inner half of each channel pattern 40 is located on the first conductive line 20.

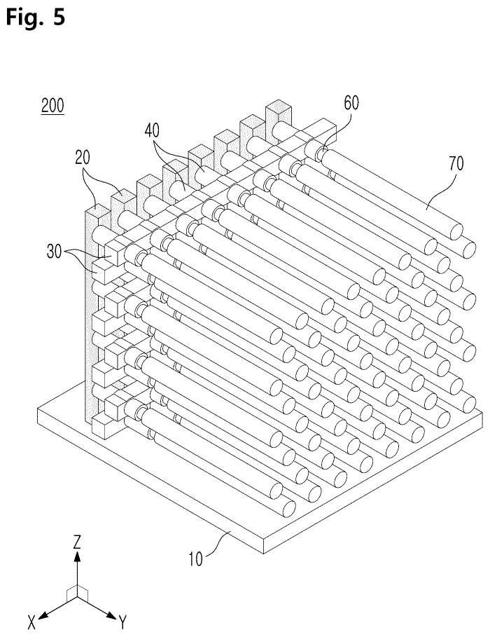

FIG. 5 is a schematic perspective view of a DRAM device comprising the vertical channel transistor of FIG. 1.

Referring to FIG. 5, a capacitor 70 is connected on the vertical channel transistor 100, through which a DRAM device 200 such as a DRAM may be implemented.

The capacitor 70 may be electrically connected to the channel pattern 40, and a contact plug 60 may be further comprised between the capacitor 70 and the channel pattern 40. The vertical channel transistor 100 may be utilized in a non-memory such as a central processing unit (CPU), as well as in a memory as described above.

The present invention is not particularly limited to methods for manufacturing a vertical channel transistor and a DRAM device comprising the same, but they may be manufactured by, for example, the following method.

On the substrate 10, a first conductive line 20 is first formed vertically, electrodes 40u and 40l are formed on an upper part and a lower part of the first conductive line 20, and a plurality of channel patterns 40 extending in a third direction (e.g., a Y-axis direction) are formed. The upper electrode 40u of the plurality of channel patterns may be, for example, a source region, and the lower electrode 40l of the plurality of channel patterns may be, for example, a drain region. The first conductive line 20 may have a structure in common contact with the lower electrode 40l of the plurality of channel patterns 40.

The plurality of channel patterns 40 may be arranged in a honeycomb structure on a plane (e.g., an XZ plane) perpendicular to the substrate 10.

Next, a gate 50 is formed to enclose a side surface between the upper electrode 40u and the lower electrode 40l of the plurality of channel patterns 40. The gate 50 may comprise a gate insulating pattern 52 and a gate conducting pattern 54. In this case, preferably, the vertical height of the gate 50 is formed to be greater than at least a sum of vertical heights of the first and second sublines 30u and 30l, which will be mentioned later.

Here, the first conductive line 20 may be formed in a first direction (e.g., a Z-axis direction), and the plurality of channel patterns 40 located on the single bit line are arranged in zigzag along both edges of the single bit line.

Next, a plurality of first and second word lines 30u and 30l are formed to be in common contact with the gate 50 formed on a side surface of the plurality of channel patterns 40. Here, the first and second word lines 30u and 30l may be formed in a second direction (e.g., an X-axis direction), and may be provided alternating with each other in a first direction (e.g., a Z-axis direction). Each of the first and second word lines 30u and 30l penetrates the center of the plurality of channel patterns 40 arranged in a straight line in the second direction (e.g., an X-axis direction).

Thereafter, a series of subsequent processes known in the art may be performed one after the other to complete the manufacturing of a vertical channel transistor according to the present invention and a DRAM device comprising the same.

### First Modification Example

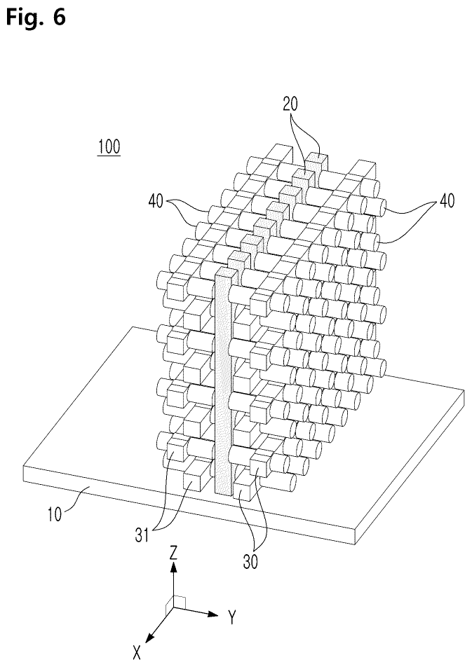

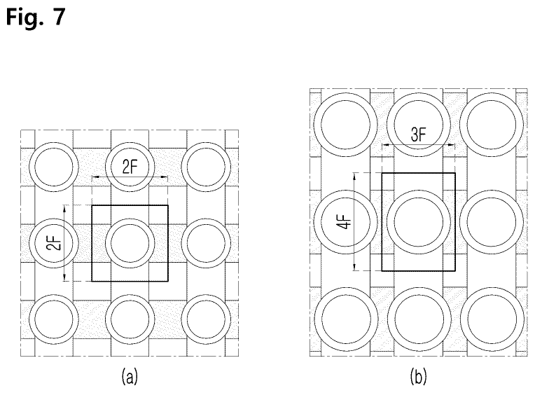

FIG. 6 is a cross-sectional view of a vertical channel transistor according to a first modification example. In FIG. 6, like reference numerals indicate like components in the embodiment described above, and detailed descriptions thereon are omitted or simplified.

The first modification example comprises a first conductive line 20 oriented in a first direction (e.g., a Z-axis direction) perpendicular to an upper surface of the substrate 10, a channel pattern 40 of a honeycomb structure on both sides of the first conductive line 20 in a third direction (e.g., a Y-axis direction), a plurality of second conductive lines 30 located on the first conductive line 20, and disposed parallel to each other in a second direction (e.g., an X-axis direction) perpendicular to the first conductive line at predetermined intervals, and a plurality of third conductive lines 31 located on the first conductive line 20, contacting the first conductive line on an opposite side of the second conductive line 30, and disposed parallel to each other in a second direction (e.g., an X-axis direction) perpendicular to the first conductive line 20 at predetermined intervals.

Thus, as illustrated in FIG. 6, the plurality of second conductive lines and third conductive lines have a structure parallel to each other. The second conductive line 30 may comprise a first subline 30u and a second subline 30l which are at different distances from the first conductive line 20, and the third conductive line 31 may comprise a third subline 31u and a fourth subline 31l which are at different distances from the first conductive line 20.

Unlike the convention transistor in which channel patterns or capacitors can be formed only on one side, the bi-directional three-dimensional stacked DRAM device formed as above has the advantage of forming channel patterns or capacitors on both sides, preventing floating, and securing high density in a smaller substrate area with a reduced minimum feature size.

The technical reasons why the minimum feature size F can be easily reduced as the adjacent word lines are disposed at different heights from the bit lines are described in more details below.

In the field of DRAM devices, the minimum feature size F is an important element in determining the density and performance of a device. The minimum feature size F means the smallest line width which can be drawn within a semiconductor circuit, and is generally the smallest among (1) the width of a word line, (2) the width of a bit line, (3) the intervals between adjacent word lines, and (4) the intervals between adjacent bit lines.

The smaller the minimum feature size F, the higher the transistor density of a semiconductor chip, the smaller the chip size, and the lower the power consumption. Therefore, in the field of DRAM devices, technological advancements have been directed towards adopting the smallest feature size F.

However, such minimum feature size is not something that can be reduced arbitrarily, and is usually determined by the level of technological advancement at the time of manufacturing. Specifically, the minimum feature size can be determined by the resolution capabilities of photolithography equipment, and the quality and performance of the photoresist.

(a) of FIG. 7 is a plan view of a DRAM device comprising a vertical channel transistor with conventional 4F2 structure. In (a) of FIG. 7, (1) the width of the word line, (2) the width of the bit line, (3) the intervals between adjacent word lines, and (4) the intervals between adjacent bit lines are all set to F, resulting in a 4F2 structure.

(b) of FIG. 7 is a plan view of a DRAM device comprising a vertical channel transistor wherein (3) the intervals between adjacent word lines are reduced to one-half (1/2) compared to (1) the width of the word line, (2) the width of the bit line, and (4) the intervals between adjacent bit lines. In this case, (3) the intervals between adjacent word lines become the minimum feature size F, and this minimum feature size F is determined by the level of technological advancement at the time of manufacturing, resulting in an increase in the area of unit cell (12F2=4F×3F). In other words, it is never preferable to adjust the intervals between adjacent word lines in order to reduce the area of unit cell.

However, in the present invention, the horizontal interval between the adjacent first word lines and second word lines can be adjusted to any extent when the interval between adjacent first lines and the interval between adjacent second word lines each has a minimum feature size F or greater. This is because word lines formed in different planes (different heights) are formed in different processes, and thus not affected by the minimum feature size, which is determined by the technology level at the time of manufacturing. In theory, it is possible to adjust the horizontal interval between the adjacent first word lines and second word lines up to ½F.

Therefore, the DRAM device according to an aspect of the present invention may achieve an improved capacity per unit area compared to the capacity per unit area which can be generally achieved at the level of technical progress at the time of manufacturing.

The foregoing description of the present specification has been presented for illustrative purposes, and it is apparent to a person having ordinary skill in the art that the present specification can be easily modified into other detailed forms without changing the technical idea or essential features of the present specification. Therefore, it should be understood that the forgoing embodiments are by way of example only, and are not intended to limit the present specification. For example, each component which has been described as a unitary part can be implemented as distributed parts. Likewise, each component which has been described as distributed parts can also be implemented as a combined part.

The scope of the present specification is presented by the accompanying claims, and it should be understood that all changes or modifications derived from the definitions and scopes of the claims and their equivalents fall within the scope of the present specification.

### DESCRIPTION OF REFERENCE NUMERALS

10: substrate
20: first conductive line
30: second conductive line
31: third conductive line
40: channel pattern
40l: lower electrode
40u: upper electrode
50: gate
52: gate insulating pattern
54: gate conducting pattern
60: contact plug
70: capacitor
100: vertical channel transistor
200: DRAM device

What is claimed is:

1. A DRAM device, comprising:
a substrate;
a plurality of first conductive lines oriented in a first direction perpendicular to an upper surface of the substrate, and disposed parallel to each other at predetermined intervals;
a plurality of second conductive lines located on the first conductive line, and disposed parallel to each other in a second direction perpendicular to the first conductive line at predetermined intervals;
a plurality of channel patterns arranged in a honeycomb structure on the first conductive line, the plurality of channel patterns each extending in a third direction perpendicular to both the first direction and the second direction; and
a gate insulating pattern located between the plurality of channel patterns and the plurality of second conductive lines;
wherein the plurality of second conductive lines comprise a first subline and a second subline which are at different distances from the first conductive line, and the first subline and the second subline are provided alternating with each other in the first direction, and
the plurality of channel patterns located on the single first conductive line are arranged in zigzag along both edges of the single first conductive line, and the plurality of channel patterns contacting the single second conductive line are arranged in a straight line.

2. The DRAM device of claim 1, further comprising a gate electrode arranged between the second conductive line and the gate insulating pattern.

3. A DRAM device, comprising:
a substrate;
a plurality of first conductive lines oriented in a first direction perpendicular to an upper surface of the substrate, and disposed parallel to each other at predetermined intervals;
a plurality of second conductive lines located on the first conductive line, and disposed parallel to each other in a second direction perpendicular to the first conductive line at predetermined intervals;
a plurality of third conductive lines located on the first conductive line, contacting the first conductive line on an opposite side of the second conductive line, and disposed parallel to each other in a second direction perpendicular to the first conductive line at predetermined intervals;
a plurality of channel patterns arranged in a honeycomb structure on the first conductive line, the plurality of channel patterns each extending in a third direction perpendicular to both the first direction and the second direction; and
a gate insulating pattern located between the plurality of channel patterns and the plurality of second conductive lines or the plurality of third conductive lines;
wherein the plurality of second conductive lines comprise a first subline and a second subline which are at different distances from the first conductive line, and the first subline and the second subline are provided alternating with each other in the second direction,
the plurality of third conductive lines comprise a third subline and a fourth subline which are at different distances from the first conductive line, and the third subline and the fourth subline are provided alternating with each other in the second direction, and
the plurality of channel patterns located on the single first conductive line are arranged in zigzag along both edges of the single first conductive line, and the plurality of channel patterns contacting the single second conductive line or the third conductive line are arranged in a straight line.

4. The DRAM device of claim 3, further comprising a gate electrode arranged between the second conductive line or the third conductive line and the gate insulating pattern.
